(19) United States
(12) Patent Application Publication
(10) Pub. No.: US 2024/0292511 A1
(43) Pub. Date: Aug. 29, 2024

(54) POSITION DETECTION APPARATUS, POSITION DETECTION METHOD, AND NON-TRANSITORY COMPUTER-READABLE MEDIUM STORING POSITION DETECTION PROGRAM

(71) Applicant: Lasertec Corporation, Yokohama (JP)

(72) Inventors: Keitaro HAYASHIDA, Yokohama-shi (JP); Tsunehito KOHYAMA, Yokohama-shi (JP)

(73) Assignee: Lasertec Corporation, Yokohama (JP)

(21) Appl. No.: 18/588,756

(22) Filed: Feb. 27, 2024

(30) Foreign Application Priority Data
Feb. 28, 2023 (JP) 2023-029043

(51) Int. Cl. H05H 1/00; G01B 15/00

(52) U.S. Cl. CPC H05H 1/0006; G01B 15/00

(57) ABSTRACT

A position detection apparatus according to the present disclosure includes a first optical system configured to focus, among light including first light and second light generated along with EUV light from plasma generated by causing a condenser lens to focus laser light on a target, the first light by the condenser lens, a first position detector configured to detect the first light focused by the first optical system, a second optical system configured to focus the second light, a second position detector configured to detect the second light focused by the second optical system, and a position detection processing unit configured to detect change of a position of the plasma from change of a spot of the first light and change of the spot of the second light.

### INCORPORATION BY REFERENCE

This application is based upon and claims the benefit of priority from Japanese patent application No. 2023-029043, filed on Feb. 28, 2023, the disclosure of which is incorporated herein in its entirety by reference.

### BACKGROUND

The present disclosure relates to a position detection apparatus, and a position detection method.

In a mask defect inspection using extreme ultraviolet (EUV) light, it is necessary to uniformly illuminate an inspection region with a stable light amount. For example, Japanese Unexamined Patent Application Publication No. 2021-001924, Japanese Unexamined Patent Application Publication No. 2014-086523, and Japanese Unexamined Patent Application Publication No. 2011-003887 disclose a light source of a laser produced plasma (LPP) scheme, which excites a target such as tin (Sn) by irradiating the target with infrared (IR) laser light to generate EUV light from the generated plasma. The EUV light taken out from the light source is utilized in a mask inspection apparatus, an exposure apparatus, or the like.

### SUMMARY

In a case where a configuration of critical illumination is employed by using a light source of an LPP scheme, if a position of a plasma bright spot (in other words, “a position of a bright point of plasma”) changes, the illumination deviates from an inspection region, which causes a problem in the inspection. In the light source of the LPP scheme, a position of the target may fluctuate, or an irradiation position of laser light may fluctuate, and thus, a point at which the plasma is generated changes. It is therefore necessary to appropriately detect the position shift of the plasma bright spot and make a correction.

An object of the present disclosure, which has been made to solve such a problem, is to provide a position detection apparatus and a position detection method capable of improving detection accuracy of a position of plasma.

A position detection apparatus according to the present disclosure includes a first optical system configured to focus first light by a condenser lens, the first light being among light including the first light and second light generated along with EUV light from plasma generated by causing the condenser lens to focus laser light on a target, a first position detector configured to detect the first light focused by the first optical system, a second optical system configured to focus the second light, a second position detector that detects the second light focused by the second optical system, and a position detection processing unit configured to detect change of a position of the plasma from change of a spot of the first light detected by the first position detector and change of the spot of the second light detected by the second position detector.

In the above-described position detection apparatus, as the first light and the second light, an EUV wavelength component in plasma light may be used or a wavelength component such as UV, visible light and IR may be used.

In the above-described position detection apparatus, when an optical axis of the condenser lens is defined as a first optical axis, the position detection processing unit may detect change of the position of the plasma in a direction of the first optical axis and change of the position of the plasma in a direction intersecting with the first optical axis from a position of the spot of the first light detected by the first position detector.

In the above-described position detection apparatus, when an optical axis of the condenser lens is defined as a first optical axis, the position detection processing unit may detect change of the position of the plasma in a direction of the first optical axis from a size of the spot of the first light detected by the first position detector.

In the above-described position detection apparatus, the second optical system may include a plurality of mirrors disposed on the periphery of a collector mirror that reflects the EUV light emitted from the plasma, when a main optical axis of the EUV light incident on the collector mirror is defined as a second optical axis, the second light incident on the plurality of mirrors may include a plurality of light fluxes having optical axes each in a relative symmetry with respect to the second optical axis, and the position detection processing unit may detect change of the position of the plasma in a direction of the second optical axis and change of the position of the plasma in a direction intersecting with the second optical axis from a position of the spot of the second light detected by the second position detector.

In the above-described position detection apparatus, the second optical system may include a plurality of mirrors disposed on the periphery of a collector mirror that reflects the EUV light emitted from the plasma, when a main optical axis of the EUV light incident on the collector mirror is defined as a second optical axis, the second light incident on the plurality of mirrors may include a plurality of light fluxes having optical axes each in a relative symmetry with respect to the second optical axis, and the position detection processing unit may detect change of the position of the plasma in a direction of the second optical axis from a size of the spot of the second light detected by the second position detector.

In the above-described position detection apparatus, the position detection processing unit may calculate change of an optical axis of an EUV light optical system for correcting the optical axis of the EUV light optical system that focuses the EUV light based on the detected change of the position of the plasma.

A position detection method according to the present disclosure includes a step of focusing, among light including first light and second light generated along with EUV light from plasma by causing a condenser lens to focus laser light on a target, the first light by a first optical system including the condenser lens, a step of detecting by a first position detector, the first light focused by the first optical system, a step of focusing the second light by a second optical system, a step of detecting by a second position detector, the second light focused by the second optical system, and a step of detecting by a position detection processing unit, change of a position of the plasma from change of a spot of the first light detected by the first position detector and change of the spot of the second light detected by the second position detector.

In the above-described position detection method, as the first light and the second light, an EUV wavelength component in plasma light may be used, or a wavelength component such as UV, visible light and IR may be used.

In the above-described position detection method, in the step of detecting by the position detection processing unit, when an optical axis of the condenser lens is defined as a first optical axis, change of the position of the plasma in a direction of the first optical axis and change of the position of the plasma in a direction intersecting with the first optical axis may be detected from a position of the spot of the first light detected by the first position detector.

In the above-described position detection method, in the step of detecting by the position detection processing unit, when an optical axis of the condenser lens is defined as a first optical axis, change of the position of the plasma in a direction of the first optical axis may be detected from a size of the spot of the first light detected by the first position detector.

In the above-described position detection method, in the step of detecting by the position detection processing unit, the second optical system may include a plurality of mirrors disposed on the periphery of a collector mirror that reflects the EUV light emitted from the plasma, when a main optical axis of the EUV light incident on the collector mirror is defined as a second optical axis, the second light incident on the plurality of mirrors may include a plurality of light fluxes having optical axes each in a relative symmetry with respect to the second optical axis, change of the position of the plasma in a direction of the second optical axis and change of the position of the plasma in a direction intersecting with the second optical axis may be detected from a position of the spot of the second light detected by the second position detector.

In the above-described position detection method, in the step of detecting by the position detection processing unit, the second optical system may include a plurality of mirrors disposed on the periphery of a collector mirror that reflects the EUV light emitted from the plasma, when a main optical axis of the EUV light incident on the collector mirror is defined as a second optical axis, the second light incident on the plurality of mirrors may include a plurality of light fluxes having optical axes each in a relative symmetry with respect to the second optical axis, and change of the position of the plasma in a direction of the second optical axis may be detected from a size of the spot of the second light detected by the second position detector.

The above-described position detection method may further include a step of calculating change of an optical axis of an EUV light optical system for correcting the optical axis of the EUV light optical system that focuses the EUV light based on the change of the position of the plasma detected by the position detection processing unit.

According to the present disclosure, it is possible to provide a position detection apparatus and a position detection method capable of improving detection accuracy of a position of plasma. The above and other objects, features and advantages of the present disclosure will become more fully understood from the detailed description given hereinbelow and the accompanying drawings which are given by way of illustration only, and thus are not to be considered as limiting the present disclosure.

### BRIEF DESCRIPTION OF DRAWINGS

FIG. 1 is a cross-sectional view illustrating a light source according to a first embodiment;

FIG. 2 is a perspective view illustrating a container of the light source according to the first embodiment;

FIG. 3 is a configuration diagram illustrating the light source and a position detection apparatus according to the first embodiment;

FIG. 4 is a view illustrating first light and second light in a case where a position of plasma according to the first embodiment changes in a direction of a first optical axis;

FIG. 5 is a view illustrating a spot of the first light detected by a first position detector and a spot of the second light detected by a second position detector before and after change in a case where the position of the plasma in a target changes in the position detection apparatus according to the first embodiment;

FIG. 6 is a view illustrating the first light and the second light in a case where the position of the plasma according to the first embodiment changes in a direction of a second optical axis;

FIG. 7 is a view illustrating the first light and the second light in a case where the position of the plasma according to the first embodiment changes in the direction of the first optical axis and in the direction of the second optical axis;

FIG. 8 is a block diagram illustrating a position detection processing unit in the position detection apparatus according to the first embodiment;

FIG. 9 is a flowchart indicating a position detection method according to the first embodiment; and

FIG. 10 is a configuration diagram illustrating a light source and a position detection apparatus according to a second embodiment.

### DESCRIPTION OF EMBODIMENTS

A specific configuration of the present embodiment will be described below with reference to the drawings. The following description indicates preferred embodiments of the present disclosure, and a scope of the present disclosure is not limited to the following embodiments. In the following description, substantially similar components are denoted by the same reference numerals.

### First Embodiment

A position detection apparatus according to a first embodiment will be described. The position detection apparatus of the present embodiment, for example, detects a position of a bright point of plasma that generates EUV light in a light source of the EUV light. The light source excites a target such as tin by irradiating the target with laser light including IR light and generates the EUV light from the generated plasma. The light source is a light source of illumination light that illuminates an inspection target in an inspection apparatus. Further, the light source may be used as a light source of exposure light in an exposure apparatus. As an example of the light source, an example will be described where molten metal held in a container is the target. Note that the light source is not limited to that for irradiating molten metal held in a container as the target and may be a light source irradiating solid metal, a droplet, or the like, that generates plasma by being irradiated with laser light, as the target.

The position of the bright point of the plasma can be subjected to change due to factors such as pointing of laser light and a liquid level of the target. In a case where the inspection apparatus has a configuration of critical illumination, if the position of the bright point of the plasma changes, illumination deviates from an inspection region, and thus, it is necessary to appropriately detect the position shift of the plasma bright spot and make a correction. The position of the bright point of the plasma can be displaced in an arbitrary three-dimensional direction, and thus, it is necessary to determine and control the position of the bright point in a three-dimensional coordinate system. Thus, in the present embodiment, position detectors such as cameras are disposed on different axes to determine a coordinate of the position of the bright point of the plasma. Note that in the following description, the position of the bright point of the plasma and the position of the plasma will be described as the same position. First, <Light source> will be described, and then, <Configuration of position detection apparatus> will be described.

### <Light Source>

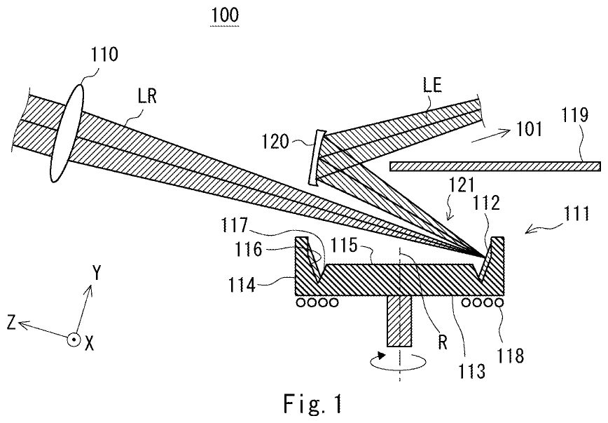

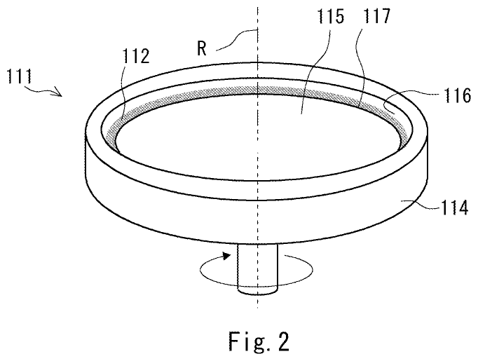

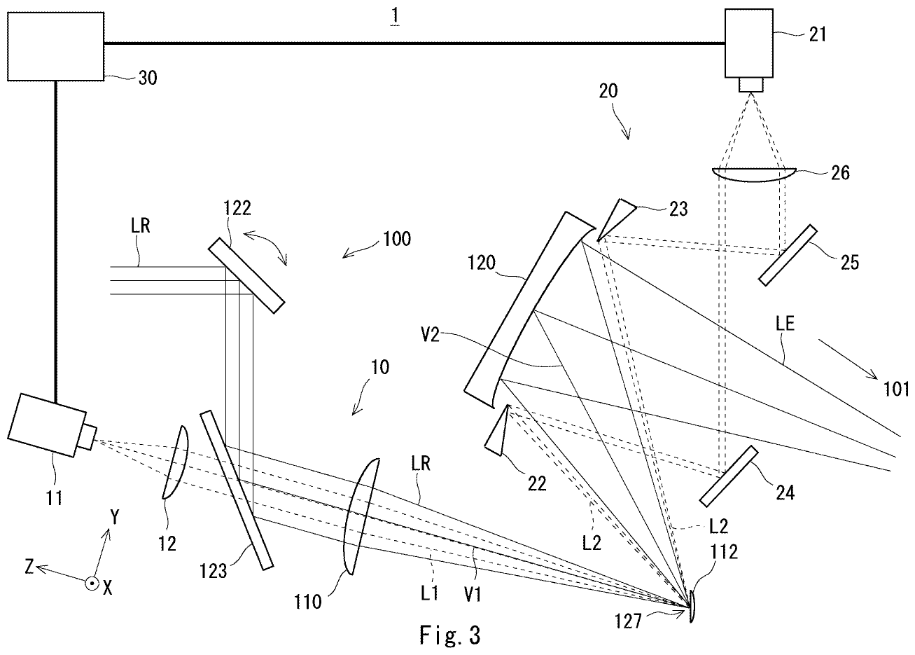

FIG. 1 is a cross-sectional view illustrating a light source according to the first embodiment. FIG. 2 is a perspective view illustrating a container of the light source according to the first embodiment. FIG. 3 is a configuration diagram illustrating the light source and a position detection apparatus according to the first embodiment. As illustrated in FIG. 1 to FIG. 3, a light source 100 includes a container 111. The container 111 is, for example, a crucible and can melt metal inside. The container 111 holds a target 112 such as molten metal that generates plasma 127 by being irradiated with laser light LR. The target 112 is, for example, molten metal held in the container 111. Note that the target 112 is not limited to the molten metal held in the container 111 and may be solid metal, a droplet, or the like, if the target 112 is a substance that generates the plasma 127 by being irradiated with the laser light LR. The molten metal is, for example, molten tin (Sn) or molten lithium (Li), but the molten metal is not limited to molten tin or molten lithium if plasma can be generated through irradiation with the laser light LR.

The container 111 has a rotation axis R and rotates about the rotation axis R. The container 111 has, for example, a cylindrical shape in which one opening portion is closed. The closed portion of the container 111 will be referred to as a bottom portion 113. The cylindrical portion of the container 111 will be referred to as a cylindrical portion 114. The rotation axis R of the container 111 extends, for example, in a vertical direction. An internal surface of the bottom portion 113 will be referred to as a bottom surface 115. An internal surface of the cylindrical portion 114 will be referred to as an inner peripheral surface 116. A groove 117 may be formed at a joint portion between the bottom portion 113 and the cylindrical portion 114.

The inner peripheral surface 116 formed so as to enclose the rotation axis R may include a cylindrical portion for which a distance from the rotation axis R is constant or may include a mortar-shaped portion expanding outward towards the above. For example, the mortar-shaped portion of the inner peripheral surface 116 is connected to the groove 117.

The light source 100 may include a heater 118, a debris shield 119, a collector mirror 120, a mirror 122, a mirror 123, and a condenser lens 110 in addition to the container 111. The target 112 such as molten metal can be formed inside the container 111 through heating by the heater 118. EUV light LE is generated from the plasma 127 generated by irradiating the target 112 with the laser light LR. The collector mirror 120 reflects the EUV light LE emitted from the plasma 127. The collector mirror 120 reflects the generated EUV light LE and guides the EUV light LE to an apparatus such as an inspection apparatus 101. The debris shield 119 is disposed at an opening portion 121 so as to cover the target 112.

The light source 100 may include an excitation laser that generates the laser light LR or may irradiate the target 112 by introducing the laser light LR from an excitation laser installed outside the light source 100. The laser light LR is, for example, IR laser light. The laser light LR is focused by the condenser lens 110 and irradiates the target 112.

As illustrated in FIG. 3, the laser light LR is, for example, incident on the condenser lens 110 via the mirrors 122 and 123. The mirror 122 is, for example, a piezo steering mirror. The piezo steering mirror can easily align the optical axis of the laser light LR. The mirror 123 is a half mirror or a beam splitter.

The condenser lens 110 focuses the laser light LR on the target 112. The target 112 is excited by being irradiated with the laser light LR. By this means, the target 112 generates the plasma 127 and generates the EUV light LE. The generated EUV light LE is taken out on a side of an apparatus such as the inspection apparatus 101.

### <Configuration of Position Detection Apparatus>

Next, the position detection apparatus of the present embodiment will be described. As illustrated in FIG. 3, the position detection apparatus 1 includes a first optical system 10, a first position detector 11, a second optical system 20, a second position detector 21, and a position detection processing unit 30.

The first optical system 10 focuses light generated along with the EUV light LE from the plasma 127 generated by causing the condenser lens 110 to focus the laser light LR on the target 112. The light generated along with the EUV light LE includes first light L1 and second light L2. The first optical system 10 focuses the first light L1 among light including the first light L1 and the second light L2 by the condenser lens 110. The first light L1 and the second light L2 may include UV light, visible light or IR light or may include the EUV light LE. In other words, the first light L1 and the second light L2 includes at least one of the EUV light, the UV light, the visible light and the IR light.

The first optical system 10 includes, for example, the condenser lens 110 and a lens 12. Thus, the condenser lens 110 focuses the laser light LR in the light source 100 and focuses the first light L1 in the first optical system 10. The optical axis of the condenser lens 110 may be coincident with the optical axis of the lens 12. The optical axis of the condenser lens 110 will be referred to as a first optical axis V1. A mirror 123 is disposed between the condenser lens 110 and the lens 12. The first optical system 10 may include an optical member other than these.

Here, for convenience of explanation of the position detection apparatus 1, an XYZ orthogonal coordinate axis system is introduced. For example, the first optical axis V1 of the condenser lens 110 that focuses the laser light LR on the target 112 is defined as a Z axis direction, and two directions orthogonal to the first optical axis V1 are defined as an X axis direction and a Y axis direction.

The condenser lens 110 is disposed at a position facing the target 112. For example, the condenser lens 110 is disposed in a +Z axis direction of the target 112. The condenser lens 110 focuses the first light L1 generated along with the EUV light LE from the target 112. The condenser lens 110 is also used as a lens that focuses the laser light LR and irradiates the target 112.

The laser light LR is reflected at the mirrors 122 and 123, and then passes through a central portion including the first optical axis V1 of the condenser lens 110 and is focused on the target 112. The first light L1 generated from the target 112 passes through the central portion including the first optical axis V1. Part of the first light L1 that has passed through the condenser lens 110 passes through the mirror 123. The first light L1 that has passed through the mirror 123 is incident on the lens 12. The first light L1 passes through a central portion including an optical axis of the lens 12. The lens 12 focuses the first light L1 on the first position detector 11.

The first position detector 11 detects the first light L1 focused by the first optical system 10. The first position detector 11 may detect a spot of the first light L1 as an image. The first position detector 11 outputs information on an image, or the like, of the detected spot of the first light L1 to the position detection processing unit 30. The position detection processing unit 30 detects change of a position of the plasma 127 in the target 112 from change of the spot of the first light L1 detected by the first position detector 11. For example, the first position detector 11 mainly detects pointing fluctuation of the laser light LR by detecting the first light L1 having the first optical axis V1 that is made coincident with an incidence axis of the laser light LR to be used to emit plasma, as the main optical axis.

The second optical system 20 focuses the second light L2 generated along with the EUV light LE. The second optical system 20 includes a plurality of mirrors and the lens 26. The plurality of mirrors include, for example, a mirror 22, a mirror 23, a mirror 24, and a mirror 25. The second optical system 20 may include an optical member other than these.

The mirrors 22 and 23 are disposed on the periphery of the collector mirror 120. Thus, the second optical system 20 includes a plurality of mirrors 22 and 23 disposed on the periphery of the collector mirror 120. The mirrors 22 and 23 may be disposed at positions symmetric about the center of a light receiving surface of the collector mirror 120. The mirrors 22 and 23 may be disposed so as to overlap with part of the periphery of the collector mirror 120. The mirrors 22 and 23 may function as a cutout mirror of the EUV light, and the like, generated from the plasma 127.

The second light L2 generated from the target 112 is incident on the mirrors 22 and 23. Thus, the second light L2 may include a plurality of light fluxes including a light flux that is incident on the mirror 22 and a light flux that is incident on the mirror 23. The main optical axis of the EUV light LE incident on the collector mirror 120 will be referred to as a second optical axis V2. In this case, the second light L2 incident on the plurality of mirrors 22 and 23 include a plurality of light fluxes having optical axes each in a relative symmetry with respect to the second optical axis V2.

The mirror 22 reflects the incident second light L2. The second light L2 reflected at the mirror 22 is incident on the mirror 24. The mirror 24 reflects the incident second light L2. The second light L2 reflected at the mirror 24 is incident on the lens 26. The mirror 23 reflects the incident second light L2. The second light L2 reflected at the mirror 23 is incident on the mirror 25. The mirror 25 reflects the incident second light L2. The second light L2 reflected at the mirror 25 is incident on the lens 26. The lens 26 focuses the incident second light L2 on the second position detector 21. Specifically, the lens 26 forms images of the second light L2 incident on the mirror 22 and the second light L2 incident on the mirror 23 at the same point of the second position detector 21.

The second position detector 21 detects the second light L2 focused by the second optical system 20. Specifically, the second position detector 21 detects the second light L2 whose images are formed at the same point by the lens 26. The second light L2 whose images are formed at the same point includes the second light L2 incident on the mirror 22 and the second light L2 incident on the mirror 23. This enables the second position detector 21 to obtain information equivalent to information obtained when viewed from the second optical axis V2 that is the main optical axis of the EUV light LE. The second position detector 21 may detect a spot of the second light L2 as an image. The second position detector 21 outputs information on an image, or the like, of the detected spot of the second light L2 to the position detection processing unit 30. The position detection processing unit 30 detects change of the position of the plasma 127 in the target 112 from change of the spot of the second light L2 detected by the second position detector 21.

The first optical axis V1 intersects with the second optical axis V2. The first optical axis V1 extends in a +Z axis direction from the plasma 127. The second optical axis V2 extends in a direction intersecting with the first optical axis V1 from the plasmas 127. In the position detection apparatus 1 of the present embodiment, the first position detector 11 is disposed on the optical axis including the first optical axis V1. Further, in the position detection apparatus 1, the second position detector 21 is disposed on the optical axis including the second optical axis V2. By this means, the position detection apparatus 1 detects a position of the plasma 127 using the first optical axis V1 and the second optical axis V2. This makes it possible for the position detection apparatus 1 to determine the position of the plasma 127 in a three-dimensional coordinate system.

The second optical axis V2 preferably has a large amount of component orthogonal to the first optical axis V1. Specifically, an angle formed by the first optical axis V1 and the second optical axis V2 is preferably closer to 90°. This makes it possible to improve detection accuracy of the position of the plasma 127.

The second optical axis V2 is preferably made coincident with the optical axis of the EUV light optical system. By this means, detection accuracy is improved. Further, it is possible to simulate motion of a bright point of the plasma 127 in an inspection region in a case where the position of the target 112 changes.

Next, change of the spot of the first light L1 and the spot of the second light L2 in a case where the position of the plasma 127 changes will be described. First, <Change of position of plasma in first optical axis direction> and <Change of position of plasma in second optical axis direction> will be described, and then, <Change of position of plasma in first optical axis direction and in second optical axis direction> will be described.

### <Change of Position of Plasma in First Optical Axis Direction>

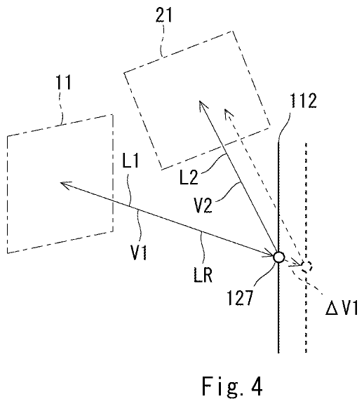

FIG. 4 is a view illustrating the first light L1 and the second light L2 in a case where the position of the plasma 127 according to the first embodiment changes in a direction of the first optical axis V1. As illustrated in FIG. 4, for example, in a case where a liquid level of the target 112 changes, the position of the plasma 127 changes along the first optical axis V1. Description will be provided separately in a case where change ΔV1 of the position of the plasma 127 is equal to or less than a focal depth D1 of the condenser lens 110 and equal to or less than a focal depth D2 of the collector mirror 120, and in a case where the change ΔV1 of the position of the plasma 127 is greater than the focal depth D1 of the condenser lens 110 and is greater than the focal depth D2 of the collector mirror 120.

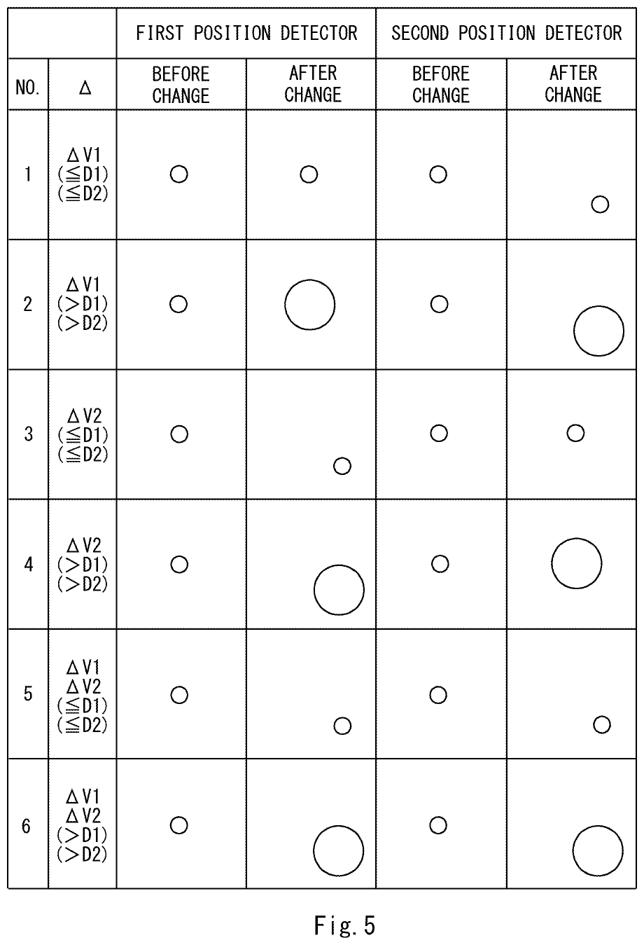

FIG. 5 is a view illustrating the spot of the first light L1 detected by the first position detector 11 and the spot of the second light L2 detected by the second position detector 21 before and after change in a case where the position of the plasma 127 in the target 112 changes in the position detection apparatus 1 according to the first embodiment. No. 1 in FIG. 5 illustrates change of the position which is equal to or less than the focal depths D1 and D2 in a case where the position of the plasma 127 changes in the direction of the first optical axis V1. No. 2 in FIG. 5 illustrates change of the position which is greater than the focal depths D1 and D2 in a case where the position of the plasma 127 changes in the direction of the first optical axis V1. No. 3 in FIG. 5 illustrates change of the position which is equal to or less than the focal depths D1 and D2 in a case where the position of the plasma 127 changes in a direction of the second optical axis V2. No. 4 in FIG. 5 illustrates change of the position which is greater than the focal depths D1 and D2 in a case where the position of the plasma 127 changes in the direction of the second optical axis V2. No. 5 in FIG. 5 illustrates change of the position which is equal to or less than the focal depths D1 and D2 in a case where the position of the plasma 127 changes in the directions of the first optical axis V1 and the second optical axis V2. No. 6 in FIG. 5 illustrates change of the position which is greater than the focal depths D1 and D2 in a case where the position of the plasma 127 changes in the directions of the first optical axis V1 and the second optical axis V2.

As illustrated in No. 1, in a case where the change ΔV1 of the position of the plasma 127 in the direction of the first optical axis V1 is equal to or less than the focal depths D1 and D2, the change ΔV1 of the position does not affect a size of the spot, that is, blurring of the spot of the first light L1 before and after the change. Thus, in the first position detector 11, the size of the spot does not change. Further, in the first position detector 11, the position of the spot does not change.

Further, the change ΔV1 of the position does not affect a size of the spot, that is, blurring of the spot of the second light L2 before and after the change. Thus, in the second position detector 21, the size of the spot does not change. However, the first optical axis V1 intersects with the second optical axis V2, and thus, the second position detector 21 detects the change ΔV1 of the position of the plasma 127 in the direction of the first optical axis V1 as change of the position of the spot of the second light L2.

As illustrated in No. 2, in a case where the change ΔV1 of the position of the plasma 127 in the direction of the first optical axis V1 is greater than the focal depths D1 and D2, the change ΔV1 of the position affects the size of the spot, that is, blurring of the spot of the first light L1 before and after the change. Thus, in the first position detector 11, the size of the spot changes. On the other hand, in the first position detector 11, the position of the spot does not change.

Further, the change ΔV1 of the position affects the size of the spot, that is, blurring of the spot of the second light L2 before and after the change. Thus, in the second position detector 21, the size of the spot changes. The first optical axis V1 intersects with the second optical axis V2, and thus, the second position detector 21 detects the change ΔV1 of the position of the plasma 127 in the direction of the first optical axis V1 as change of the position of the spot of the second light L2.

### <Change of Position of Plasma in Second Optical Axis Direction>

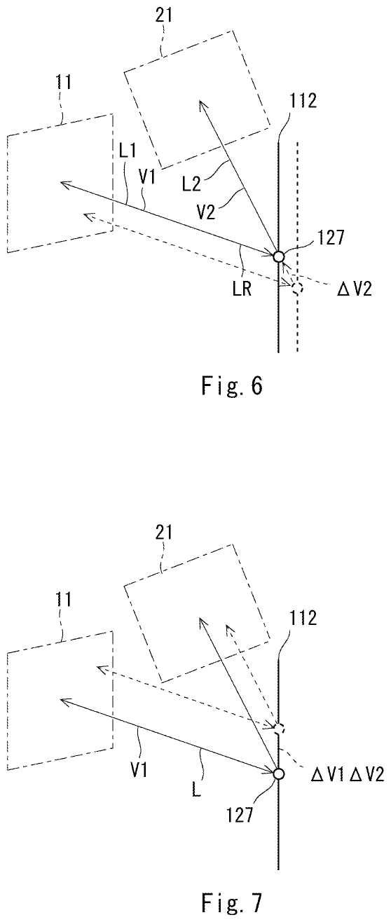

Next, a case where the position of the plasma 127 changes in the direction of the second optical axis V2 will be described. FIG. 6 is a view illustrating the first light L1 and the second light L2 in a case where the position of the plasma 127 according to the first embodiment changes in the direction of the second optical axis V2. As illustrated in FIG. 6, for example, in a case where the liquid level of the target 112 changes, and pointing of the laser light LR changes, the position of the plasma 127 may change along the second optical axis V2. Description will be provided separately in a case where the change ΔV2 of the position of the plasma 127 is equal to or less than the focal depths D1 and D2, and in a case where the change ΔV2 of the position of the plasma 127 is greater than the focal depths D1 and D2.

As illustrated in No. 3 in FIG. 5, in a case where the change ΔV2 of the position of the plasma 127 in the direction of the second optical axis V2 is equal to or less than the focal depths D1 and D2, the change ΔV2 of the position does not affect the size of the spot, that is, blurring of the spot of the first light L1 before and after the change. Thus, in the first position detector 11, the size of the spot does not change. However, the first optical axis V1 intersects with the second optical axis V2, and thus, the first position detector 11 detects the change ΔV2 of the position of the plasma 127 in the direction of the second optical axis V2 as change of the position of the spot of the first light L1.

Further, the change ΔV2 of the position does not affect the size of the spot, that is, blurring of the spot of the second light L2 before and after the change. Thus, in the second position detector 21, the size of the spot does not change. In the second position detector 21, the position of the spot does not change.

As illustrated in No. 4, in a case where the change ΔV2 of the position of the plasma 127 in the direction of the second optical axis V2 is greater than the focal depths D1 and D2, the change ΔV2 of the position affects the size of the spot, that is, blurring of the spot of the first light L1 before and after the change. Thus, in the first position detector 11, the size of the spot changes. Further, the first position detector 11 detects the change ΔV2 of the position of the plasma 127 in the direction of the second optical axis V2 as change of the position of the spot of the first light L1.

The change ΔV2 of the position affects the size of the spot, that is, blurring of the spot of the second light L2 before and after the change. Thus, in the second position detector 21, the size of the spot changes. In the second position detector 21, the position of the spot does not change.

### <Change of Position of Plasma in First Optical Axis Direction and in Second Optical Axis Direction>

Next, a case where the position of the plasma 127 changes in the direction of the first optical axis V1 and in the direction of the second optical axis V2 will be described. FIG. 7 is a view illustrating the first light L1 and the second light L2 in a case where the position of the plasma 127 according to the first embodiment changes in the direction of the first optical axis V1 and in the direction of the second optical axis V2. As illustrated in FIG. 7, for example, in a case where pointing of the laser light LR on a liquid surface of the target 112 changes, the position of the plasma 127 includes both a component that changes along the first optical axis V1 and a component that changes along the second optical axis V2. Description will be provided separately in a case where the change ΔV1 and the change ΔV2 of the position of the plasma 127 are equal to or less than the focal depths D1 and D2, and in a case where the change ΔV1 and the change ΔV2 of the position of the plasma 127 are greater than the focal depths D1 and D2.

As illustrated in No. 5, in a case where the change ΔV1 and the change ΔV2 of the position of the plasma 127 are equal to or less than the focal depths D1 and D2, the change ΔV1 and the change ΔV2 of the position do not affect the size of the spot, that is, blurring of the spot of the first light L1 before and after the change. Thus, in the first position detector 11, the size of the spot does not change. However, the first position detector 11 detects the change ΔV1 and the change ΔV2 of the position of the plasma 127 as change of the position of the spot of the first light L1.

Further, the change ΔV1 and the change ΔV2 of the position do not affect the size of the spot, that is, blurring of the spot of the second light L2 before and after the change. Thus, in the second position detector 21, the size of the spot does not change. However, the second position detector 21 detects the change ΔV1 and the change ΔV2 of the position of the plasma 127 as change of the position of the spot of the second light L2.

As illustrated in No. 6, in a case where the change ΔV1 and the change ΔV2 of the position of the plasma 127 are greater than the focal depths D1 and D2, the change ΔV1 and the change ΔV2 of the position affect the size of the spot, that is, blurring of the spot of the first light L1 before and after the change. Thus, in the first position detector 11, the size of the spot changes. Further, the first position detector 11 detects the change ΔV1 and the change ΔV2 of the position of the plasma 127 as change of the position of the spot of the first light L1.

Further, the change ΔV1 and the change ΔV2 of the position affect the size of the spot, that is, blurring of the spot of the second light L2 before and after the change. Thus, in the second position detector 21, the size of the spot changes. Further, the second position detector 21 detects the change ΔV1 and the change ΔV2 of the position of the plasma 127 as change of the position of the spot of the second light L2.

The position detection processing unit 30 detects change of the position of the plasma 127 in the direction of the first optical axis V1 and change of the position of the plasma 127 in the direction intersecting with the first optical axis V1 from the position of the spot of the first light L1 detected by the first position detector 11. For example, in a case where the position of the spot of the first light L1 does not change, the position detection processing unit 30 detects that the position of the plasma 127 has not changed or that the position of the plasma 127 has changed in the direction of the first optical axis V1. On the other hand, in a case where the position of the spot of the first light L1 changes, the position detection processing unit 30 detects that the position of the plasma 127 has changed to, for example, have a component orthogonal to the first optical axis V1.

Further, the position detection processing unit 30 detects change of the position of the plasma 127 in the direction of the second optical axis V2 and change of the position of the plasma 127 in the direction intersecting with the second optical axis V2 from the position of the spot of the second light L2 detected by the second position detector 21. For example, in a case where the position of the spot of the second light L2 does not change, the position detection processing unit 30 detects that the position of the plasma 127 has not changed or that the position of the plasma 127 has changed in the direction of the second optical axis V2. On the other hand, in a case where the position of the spot of the second light L2 changes, the position detection processing unit 30 detects that the position of the plasma 127 has changed to, for example, have a component orthogonal to the second optical axis V1.

Further, the position detection processing unit 30 detects change of the position of the plasma 127 in the direction of the first optical axis V1 from the size of the spot of the first light L1 detected by the first position detector 11. Further, the position detection processing unit 30 detects change of the position of the plasma 127 in the direction of the second optical axis V2 from the size of the spot of the second light L2 detected by the second position detector 21.

The position detection processing unit 30 can extract change of a specific position of the plasma 127 by subtracting one detection result from the detection results of the first position detector 11 and the second position detector 21. For example, the position detection processing unit 30 can extract only change of the liquid level of the target 112 by subtracting the detection result of the second position detector 21 from the detection results. Further, the position detection processing unit 30 can extract only change of pointing of the laser light LR by subtracting change of the liquid level detected by the first position detector 11 from the detection results. In this manner, the position detection processing unit 30 may extract a component of liquid level fluctuation of the target 112 alone by subtracting pointing fluctuation of the laser light LR from the change of the position of the plasma 127 or may extract a component of pointing fluctuation of the laser light LR alone by subtracting liquid level fluctuation from the change of the position of the plasma 127.

The optical axis of the EUV light optical system that focuses the EUV light LE may be corrected based on the detected change of the position of the plasma 127. For example, if the position of the plasma 127 does not change when viewed from the second position detector 21, it is estimated that an illumination position of the inspection region is kept at an appropriate position. In a case where pointing of the laser light LR or the liquid level of the target 112 fluctuates, a tilt of the mirror 122 (for example, a piezo steering mirror) of the light source 100 may be feedback controlled so that the position of the plasma 127 when viewed from the second position detector 21 does not change.

In the present embodiment, a main light beam component of the EUV light LE is used in the inspection apparatus 101, and thus cannot be used in position detection. Thus, instead, the second light L2 is cut out by the mirrors 22 and 23 disposed on the periphery of the collector mirror 120. Then, an image of the second light L2 reflected at the mirror 22 and an image of the second light L2 reflected at the mirror 23 are formed at the same point on the second position detector 21. This makes it possible to obtain information equivalent to information when viewed from the second optical axis V2.

The position detection processing unit 30 may calculate change of the optical axis of the EUV light optical system for correcting the optical axis of the EUV light optical system that focuses the EUV light LE based on the detected change of the position of the plasma 127. The position detection processing unit 30 may, for example, store the change of the position of the plasma 127 and the change of the optical axis of the EUV light optical system in association with each other in advance. Then, in a case where the position of the plasma 127 changes, the optical axis may be corrected in association with the change of the position of the plasma 127. The position detection processing unit 30 may be, for example, an information processing apparatus such as a server apparatus and a personal computer.

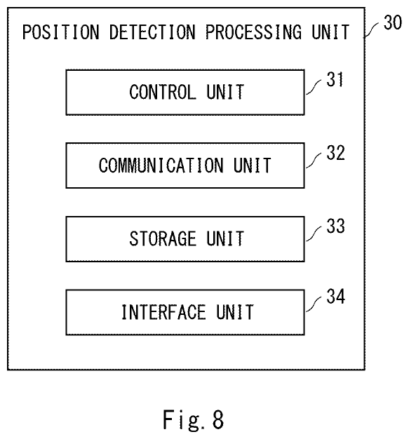

FIG. 8 is a block diagram illustrating the position detection processing unit 30 in the position detection apparatus 1 according to the first embodiment. As illustrated in FIG. 8, the position detection processing unit 30 includes a control unit 31, a communication unit 32, a storage unit 33 and an interface unit 34. The control unit 31, the communication unit 32, the storage unit 33, and the interface unit 34 respectively have functions of control means, communication means, storage means, and interface means.

The control unit 31 includes, for example, a processor such as a central processing unit (CPU), a micro processing unit (MPU), an electronic control unit (ECU), a field-programmable gate array (FPGA) and an application specific integrated circuit (ASIC). The control unit 31 has a function as an arithmetic apparatus that performs position detection processing, arithmetic processing, and the like. Further, the control unit 31 controls operation of the communication unit 32, the storage unit 33, the interface unit 34 and respective components for executing functions of respective apparatuses.

Each component of the information processing apparatus can be implemented by, for example, a program being executed under control by the control unit 31. More specifically, each component can be implemented by the control unit 31 executing a program stored in the storage unit 33. Further, each component may be implemented by a necessary program being recorded in an arbitrary non-volatile recording medium and installed as necessary. Without limited to being implemented in software by a program, each component may be implemented in a combination of any of hardware, firmware and software.

The communication unit 32 performs communication that is necessary for the position detection processing unit 30 to perform position detection processing. The storage unit 33 is, for example, a read only memory (ROM), a random access memory (RAM), or the like. The storage unit 33 has a function for storing a control program, an arithmetic program, and the like, to be executed by the control unit 31. Further, the storage unit 33 has a function for temporarily storing image data, and the like, detected by the first position detector 11 and the second position detector 21.

The interface unit 34 is, for example, a user interface. The interface unit 34 is connected to input means such as a keyboard, a touch panel, or a mouse and output means such as a display or a speaker. The interface unit accepts operation of input of data by a user (such as an operator) and outputs information to the user.

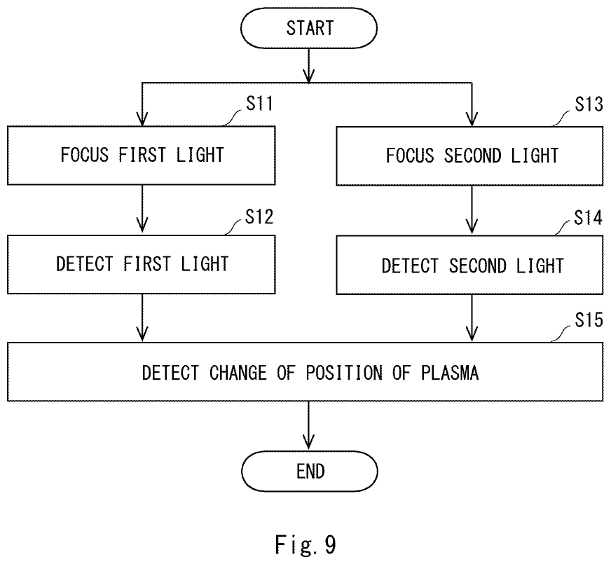

Next, a position detection method of the present embodiment will be described. FIG. 9 is a flowchart indicating the position detection method according to the first embodiment. As indicated in step S11 in FIG. 9, in the position detection method of the present embodiment, first, the first light L1 is focused. Specifically, among light generated along with the EUV light LE from the plasma 127 generated by causing the condenser lens 110 to focus the laser light LR on the target 112, the first light L1 is focused by the first optical system 10 including the condenser lens 110.

Then, as indicated in step S12, the first light L1 is detected. Specifically, the first light L1 focused by the first optical system 10 is detected by the first position detector 11.

Then, as indicated in step S13, the second light L2 is focused. Specifically, among the light generated along with the EUV light LE, the second light L2 is focused by the second optical system 20.

Then, as indicated in step S14, the second light L2 is detected. Specifically, the second light L2 focused by the second optical system 20 is detected by the second position detector 21. Note that the order of step S11 to S12 and step S13 to S14 may be changed. In other words, step S11 to S12 may be performed after step S13 to S14. Further, step S11 to S12 and step S13 to S14 may be performed in parallel.

Next, as indicated in step S15, change of the position of the plasma 127 is detected. Specifically, the change of the position of the plasma 127 is detected by the position detection processing unit 30 from the change of the spot of the first light L1 detected by the first position detector 11 and the change of the spot of the second light L2 detected by the second position detector 21.

In step S15, the change of the position of the plasma 127 in the direction of the first optical axis V1 and the change of the position of the plasma 127 in the direction intersecting with the first optical axis may be detected from the position of the spot of the first light L1 detected by the first position detector 11. Further, the change of the position of the plasma 127 in the direction of the first optical axis V1 may be detected from the size of the spot of the first light L1 detected by the first position detector 11.

Further, in step S15, the change of the position of the plasma 127 in the direction of the second optical axis V2 and the change of the position of the plasma 127 in the direction intersecting with the second optical axis V2 may be detected from the position of the spot of the second light L2 detected by the second position detector 21. Still further, the change of the position of the plasma in the direction of the second optical axis V2 may be detected from the size of the spot of the second light L2 detected by the second position detector 21.

In this manner, the position of the plasma 127 can be detected. Note that the position detection method may further include a step of calculating change of the optical axis of the EUV light optical system for correcting the optical axis of the EUV light optical system that focuses the EUV light LE based on the change of the position of the plasma 127 detected by the position detection processing unit 30.

Next, effects of the present embodiment will be described. In the position detection apparatus 1 of the present embodiment, the first light L1 and the second light L2 generated along with the EUV light LE from the plasma 127 are detected, and the change of the position of the plasma 127 is detected from the change of the spot of the first light L1 and the change of the spot of the second light L2. Thus, the change of the position of the plasma 127 is detected from change of a plurality of light beams along different optical axes, so that it is possible to improve detection accuracy of the position of the plasma 127.

Further, the position detection apparatus 1 detects the change of the position of the plasma 127 in the direction of the first optical axis V1 and the change of the position of the plasma in the direction intersecting with the first optical axis V1 from the position of the spot of the first light L1. Still further, the position detection apparatus 1 detects the change of the position of the plasma 127 in the direction of the second optical axis V2 and the change of the position of the plasma in the direction intersecting with the second optical axis V2 from the position of the spot of the second light L2. In this manner, the position detection apparatus 1 can detect the change of the position of the plasma 127 in a three-dimensional space from the change of the positions of the spots on the two optical axes, so that it is possible to improve detection accuracy.

Further, the position detection apparatus 1 may detect the change of the position of the plasma 127 in the direction of the first optical axis V1 from the size of the spot of the first light L1 or may detect the change of the position of the plasma 127 in the direction of the second optical axis V2 from the size of the spot of the second light L2. This makes it possible to detect the change of the position of the plasma 127 in the directions of the first optical axis V1 and the second optical axis V2 with high accuracy.

In a case where the change of the position of the plasma 127 is detected, the optical axis of the EUV light optical system that focuses the EUV light can be corrected based on the detected change of the position of the plasma 127, so that it is possible to improve inspection accuracy using the EUV light.

### Second Embodiment

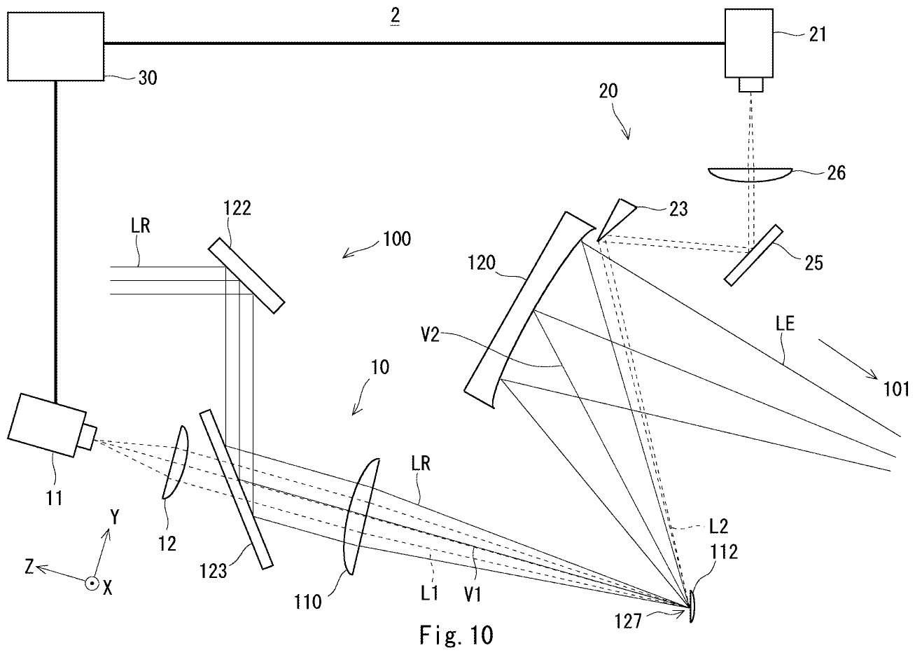

Next, a position detection apparatus according to a second embodiment will be described. The position detection apparatus of the present embodiment detects only one light flux of the second light L2 to keep the position of the plasma 127 fixed. FIG. 10 is a configuration diagram illustrating a light source and the position detection apparatus according to the second embodiment. As illustrated in FIG. 10, in a position detection apparatus 2 of the present embodiment, the second optical system 20 includes the mirror 23, the mirror 25 and the lens 26. The position detection apparatus 2 does not have to include the mirror 22 and the mirror 24.

The second light L2 generated from the target 112 is incident on the mirror 23. The mirror 23 reflects the incident second light L2. The second light L2 reflected at the mirror 23 is incident on the mirror 25. The mirror 25 reflects the incident second light L2. The second light L2 reflected at the mirror 25 is incident on the lens 26. The lens 26 focuses the incident second light L2 on the second position detector 21.

The second position detector 21 detects the second light L2 focused by the second optical system 20. Specifically, the second position detector 21 detects the second light L2 focused by the lens 26. The second position detector 21 may detect a spot of the second light L2 as an image. The second position detector 21 outputs information on an image, or the like, of the detected spot of the second light L2 to the position detection processing unit 30. The position detection processing unit 30 detects change of the position of the plasma 127 in the target 112 from the change of the spot of the second light L2 detected by the second position detector 21.

In the present embodiment, the position detection processing unit 30 does not detect a positional relationship with the main optical axis of the EUV light LE incident on the collector mirror 120. However, the position of the spot of the second light L2 in a case where the EUV light optical system is adjusted can be detected, so that it is possible to keep the position of the plasma 127 fixed. In this manner, if it is only necessary to keep the position of the plasma 127 fixed, the position of the plasma 127 may be detected using one optical axis different from the main light beam of the EUV light on the inspection apparatus side. Other configurations and effects are included in the description of the first embodiment.

While the embodiments of the present disclosure have been described above, the present disclosure can include appropriate modifications that do not impair the purpose and advantages of the present disclosure and further is not limited by the above-described embodiments. Further, the respective configurations of the first embodiment and the second embodiment may be combined as appropriate.

Further, part of all of the processing of the position detection processing unit 30 described above may be executed by a computer program. The above-described program includes a command group (or software code) for causing a computer to implement one or more functions described in the embodiments in a case where the program is loaded to the computer. The program can be stored in a non-transitory computer-readable medium or a tangible storage medium. Examples of the computer-readable medium or the tangible storage medium can include, but are not limited to, a random-access memory (RAM), a read-only memory (ROM), a flash memory, a solid-state drive (SSD), other memory techniques, a CD-ROM, a digital versatile disc (DVD), a Blu-ray (registered trademark) disc or other optical disk storages, a magnetic cassette, a magnetic tape, a magnetic disk storage or other magnetic storage devices. The program may be transmitted on a transitory computer-readable medium or a communication medium. Examples of the transitory computer-readable medium or the communication medium can include, but are not limited to, an electrical signal, an optical signal, an acoustic signal or other types of carrier signals.

Further, the following position detection program for causing a computer to execute the position detection method of the present embodiment is incorporated into technical idea of the embodiment.

A position detection program for causing a computer to execute
a step of focusing, among light including first light and second light generated along with EUV light from plasma generated by causing a condenser lens to focus laser light on a target, the first light by a first optical system including the condenser lens,
a step of detecting by a first position detector, the first light focused by the first optical system,
a step of focusing the second light by a second optical system,
a step of detecting by a second position detector, the second light focused by the second optical system, and
a step of detecting by a position detection processing unit, change of a position of the plasma from change of a spot of the first light detected by the first position detector and change of the spot of the second light detected by the second position detector.

The first and second embodiments can be combined as desirable by one of ordinary skill in the art.

From the disclosure thus described, it will be obvious that the embodiments of the disclosure may be varied in many ways. Such variations are not to be regarded as a departure from the spirit and scope of the disclosure, and all such modifications as would be obvious to one skilled in the art are intended for inclusion within the scope of the following claims.

What is claimed is:

1. A position detection apparatus comprising:
a first optical system configured to focus first light by a condenser lens, the first light being among light including the first light and second light generated along with EUV light from plasma generated by causing the condenser lens to focus laser light on a target,
a first position detector configured to detect the first light focused by the first optical system,
a second optical system configured to focus the second light,
a second position detector configured to detect the second light focused by the second optical system, and
a position detection processing unit configured to detect change of a position of the plasma from change of a spot of the first light detected by the first position detector and change of the spot of the second light detected by the second position detector.

2. The position detection apparatus according to claim 1, wherein the first light and the second light include at least one of EUV light, UV light, visible light and IR light.

3. The position detection apparatus according to claim 1, wherein when an optical axis of the condenser lens is defined as a first optical axis, the position detection processing unit detects change of the position of the plasma in a direction of the first optical axis and change of the position of the plasma in a direction intersecting with the first optical axis from a position of the spot of the first light detected by the first position detector.

4. The position detection apparatus according to claim 1, wherein when an optical axis of the condenser lens is defined as a first optical axis, the position detection processing unit detects change of the position of the plasma in a direction of the first optical axis from a size of the spot of the first light detected by the first position detector.

5. The position detection apparatus according to claim 1, wherein
the second optical system includes a plurality of mirrors disposed on the periphery of a collector mirror that reflects the EUV light emitted from the plasma,
when a main optical axis of the EUV light incident on the collector mirror is defined as a second optical axis, the second light incident on the plurality of mirrors includes a plurality of light fluxes having optical axes each in a relative symmetry with respect to the second optical axis, and
the position detection processing unit detects change of the position of the plasma in a direction of the second optical axis and change of the position of the plasma in a direction intersecting with the second optical axis from a position of the spot of the second light detected by the second position detector.

6. The position detection apparatus according to claim 1, wherein
the second optical system includes a plurality of mirrors disposed on the periphery of a collector mirror that reflects the EUV light emitted from the plasma,
when a main optical axis of the EUV light incident on the collector mirror is defined as a second optical axis, the second light incident on the plurality of mirrors includes a plurality of light fluxes having optical axes each in a relative symmetry with respect to the second optical axis, and
the position detection processing unit detects change of the position of the plasma in a direction of the second optical axis from a size of the spot of the second light detected by the second position detector.

7. The position detection apparatus according to claim 1, wherein the position detection processing unit calculates change of an optical axis of an EUV light optical system for correcting the optical axis of the EUV light optical system that focuses the EUV light based on the detected change of the position of the plasma.

8. A position detection method comprising:
a step of focusing, among light including first light and second light generated along with EUV light from plasma generated by causing a condenser lens to focus laser light on a target, the first light by a first optical system including the condenser lens;
a step of detecting by a first position detector, the first light focused by the first optical system;
a step of focusing the second light by a second optical system;
a step of detecting by a second position detector, the second light focused by the second optical system; and
a step of detecting by a position detection processing unit, change of a position of the plasma from change of a spot of the first light detected by the first position detector and change of the spot of the second light detected by the second position detector.

9. The position detection method according to claim 8, wherein the first light and the second light include at least one of EUV light, UV light, visible light and IR light.

10. The position detection method according to claim 8, wherein in the step of detecting by the position detection processing unit, when an optical axis of the condenser lens is defined as a first optical axis, change of the position of the plasma in a direction of the first optical axis and change of the position of the plasma in a direction intersecting with the first optical axis are detected from a position of the spot of the first light detected by the first position detector.

11. The position detection method according to claim 8, wherein in the step of detecting by the position detection processing unit, when an optical axis of the condenser lens is defined as a first optical axis, change of the position of the plasma in a direction of the first optical axis is detected from a size of the spot of the first light detected by the first position detector.

12. The position detection method according to claim 8, wherein
in the step of detecting by the position detection processing unit, the second optical system includes a plurality of mirrors disposed on the periphery of a collector mirror that reflects the EUV light emitted from the plasma,
when a main optical axis of the EUV light incident on the collector mirror is defined as a second optical axis, the second light incident on the plurality of mirrors includes a plurality of light fluxes having optical axes each in a relative symmetry with respect to the second optical axis, and
change of the position of the plasma in a direction of the second optical axis and change of the position of the plasma in a direction intersecting with the second optical axis are detected from a position of the spot of the second light detected by the second position detector.

13. The position detection method according to claim 8, wherein
in the step of detecting by the position detection processing unit, the second optical system includes a plurality of mirrors disposed on the periphery of a collector mirror that reflects the EUV light emitted from the plasma,
when a main optical axis of the EUV light incident on the collector mirror is defined as a second optical axis, the second light incident on the plurality of mirrors includes a plurality of light fluxes having optical axes each in a relative symmetry with respect to the second optical axis, and
change of the position of the plasma in a direction of the second optical axis is detected from a size of the spot of the second light detected by the second position detector.

14. The position detection method according to claim 8, further comprising a step of calculating change of an optical axis of an EUV light optical system for correcting the optical axis of the EUV light optical system that focuses the EUV light based on the change of the position of the plasma detected by the position detection processing unit.

15. A non-transitory computer-readable medium storing a position detection program for causing a computer to execute:
a step of focusing, among light including first light and second light generated along with EUV light from plasma generated by causing a condenser lens to focus laser light on a target, the first light by a first optical system including the condenser lens;
a step of detecting by a first position detector, the first light focused by the first optical system;
a step of focusing the second light by a second optical system;
a step of detecting by a second position detector, the second light focused by the second optical system; and
a step of detecting by a position detection processing unit, change of a position of the plasma from change of a spot of the first light detected by the first position detector and change of the spot of the second light detected by the second position detector.

16. The non-transitory computer-readable medium storing the position detection program according to claim 15, wherein the first light and the second light include at least one of EUV light, UV light, visible light, or IR light.

17. The non-transitory computer-readable medium storing the position detection program according to claim 15, wherein in the step of detecting by the position detection processing unit, when an optical axis of the condenser lens is defined as a first optical axis, change of the position of the plasma in a direction of the first optical axis and change of the position of the plasma in a direction intersecting with the first optical axis are detected from a position of the spot of the first light detected by the first position detector.

18. The non-transitory computer-readable medium storing the position detection program according to claim 15, wherein in the step of detecting by the position detection processing unit, when an optical axis of the condenser lens is defined as a first optical axis, change of the position of the plasma in a direction of the first optical axis is detected from a size of the spot of the first light detected by the first position detector.

19. The non-transitory computer-readable medium storing the position detection program according to claim 15, wherein
in the step of detecting by the position detection processing unit, the second optical system includes a plurality of mirrors disposed on the periphery of a collector mirror that reflects the EUV light emitted from the plasma,
when a main optical axis of the EUV light incident on the collector mirror is defined as a second optical axis, the second light incident on the plurality of mirrors includes a plurality of light fluxes having optical axes each in a relative symmetry with respect to the second optical axis, and
change of the position of the plasma in a direction of the second optical axis and change of the position of the plasma in a direction intersecting with the second optical axis are detected from a position of the spot of the second light detected by the second position detector.

20. The non-transitory computer-readable medium storing the position detection program according to claim 15, wherein
in the step of detecting by the position detection processing unit, the second optical system includes a plurality of mirrors disposed on the periphery of a collector mirror that reflects the EUV light emitted from the plasma,
when a main optical axis of the EUV light incident on the collector mirror is defined as a second optical axis, the second light incident on the plurality of mirrors includes a plurality of light fluxes having optical axes each in a relative symmetry with respect to the second optical axis, and
change of the position of the plasma in a direction of the second optical axis is detected from a size of the spot of the second light detected by the second position detector.
